(19) United States
(12) Patent Application Publication
(10) Pub. No.: US 2026/0018551 A1
(43) Pub. Date: Jan. 15, 2026

(54) HIGHLY INTEGRATED ENVIRONMENTAL SENSOR

(71) Applicant: Microchip Technology Incorporated, Chandler, AZ (US)

(72) Inventors: Patrick McFarland, Gilbert, AZ (US); Steve Nagel, Chandler, AZ (US); Arthur B. Eck, Gilbert, AZ (US); Bomy Chen, Newark, CA (US)

(73) Assignee: Microchip Technology Incorporated, Chandler, AZ (US)

(21) Appl. No.: 18/883,223

(22) Filed: Sep. 12, 2024

Related U.S. Application Data
(60) Provisional application No. 63/669,430, filed on Jul. 10, 2024.

(51) Int. Cl. H01L 23/00; H01L 21/4763; H01L 23/31; H01L 25/065

(52) U.S. Cl. CPC H01L 24/24; H01L 21/47635; H01L 23/3121; H01L 23/3171; H01L 23/564; H01L 24/19; H01L 25/0655; H01L 2224/19; H01L 2224/24137

(57) ABSTRACT

A system and method for a highly integrated environmental sensor and process for manufacturing said sensor is disclosed. Examples of the present disclosure may include an integrated sensor. The integrated sensor may include a redistribution layer (RDL). The integrated sensor may also include a control circuit coupled to the RDL. The integrated sensor may additionally include an analog front-end circuit coupled to the RDL and the control circuit. The integrated sensor may further include an environmental sensor coupled to the analog front-end circuit. The environmental sensor may include a first sensing element deposited in a first trench etched on the RDL using inkjet material deposition.

### PRIORITY

This application claims priority to U.S. Provisional Patent Application No. 63/669,430 filed Jul. 10, 2024, the contents of which are hereby incorporated in their entirety.

### TECHNICAL FIELD

The present disclosure relates to environmental sensors and, in particular, to a highly integrated environmental sensor and process for manufacturing said sensor.

### BACKGROUND

Environmental sensors are devices that detect and record data about the environment. Environmental sensors may be used in a variety of applications including weather monitoring (e.g., measurement of temperature or humidity) and air quality monitoring (e.g., measurement of concentration of gases, such as pollutants, in the air). Examples of environmental sensors may include temperature, humidity, pressure, light, gas, and radiation sensors.

Some environmental sensors are made of metal oxides enhanced by the addition of dopants. Metal oxides are semiconducting materials that change their electrical conductivity when exposed to various gases or environmental changes. Examples include tin dioxide (SnO₂), zinc oxide (ZnO), and titanium dioxide (TiO₂). The sensor may be enhanced by doping through the introduction of a small amount of another element (the dopant) into the crystal lattice of the metal oxide. Examples of dopants include palladium, platinum, and tungsten, or non-metals such as nitrogen and sulfur. Metal-oxide sensors may have a large footprint and use time-intensive, expensive, and low-yield manufacturing techniques.

Environmental sensors may be exposed to the environment surrounding the sensor to operate. Such exposure creates risk of ionic contamination, especially in adverse environments such as factories or seawater. This can result in the environmental sensor having poor reliability. Additionally, environmental sensors are typically paired with a separately packaged analog-to-digital converter and microcontroller, application specific integrated circuit, or processor for analysis of the data from the environmental sensor.

### SUMMARY OF THE INVENTION

Aspects provide systems and methods for a highly integrated environmental sensor and process for manufacturing said sensor. Examples of the present disclosure include an integrated sensor. The integrated sensor may include a redistribution layer (RDL). The integrated sensor may also include a control circuit coupled to the RDL. The integrated sensor may additionally include an analog front-end circuit coupled to the RDL and the control circuit. The integrated sensor may further include an environmental sensor coupled to the analog front-end circuit. The environmental sensor may include a first sensing element deposited in a first trench etched on the RDL using inkjet material deposition.

In combination with any of the above examples, an active semiconductor circuit may be contained in a sealed portion of the RDL.

In combination with any of the above examples, the first sensing element may be laser annealed.

In combination with any of the above examples, the environmental sensor may include a protective coating over the first sensing element.

In combination with any of the above examples, the integrated sensor may additionally include a second environmental sensor coupled to the analog front-end circuit. The second environmental sensor may include a second sensing element deposited in a second trench etched on the RDL using inkjet material deposition. The first sensing element may be an inorganic sensing element and the second sensing element may be an organic sensing element.

In combination with any of the above examples, the first trench may be adjacent to the second trench.

In combination with any of the above examples, the first sensing element may be exposed to an environment.

Alone or in combination with any of the above examples, examples of the present disclosure may include a method. The method may include etching a first trench in a redistribution layer (RDL). The method may also include depositing, using a nozzle, a first sensing element in the first trench. The method may additionally include coupling the first sensing element to an analog front-end circuit. The method may further include coupling the analog front-end circuit to a control circuit.

In combination with any of the above examples, the method may further include encasing an active semiconductor circuit in a sealed portion of the RDL.

In combination with any of the above examples, the method may further include laser annealing the first sensing element.

In combination with any of the above examples, the method may further include applying a protective coating over the first sensing element.

In combination with any of the above examples, the method may further include etching a second trench in the RDL. The method may also include depositing, using a second nozzle, a second sensing element in the second trench. The method may additionally include coupling the second sensing element to the analog front-end circuit. The first sensing element may be an inorganic sensing element and the second sensing element may be an organic sensing element.

In combination with any of the above examples, the first trench may be adjacent to the second trench.

In combination with any of the above examples, the method may further include exposing the first sensing element to an environment.

Alone or in combination with any of the above examples, examples of the present disclosure may include an environmental sensor. The environmental sensor may include a redistribution layer (RDL) containing a first trench etched on the RDL. The environmental sensory may additionally include a first sensing element deposited in the first trench using a material deposition process.

In combination with any of the above examples, the first sensing element may be laser annealed.

In combination with any of the above examples, the environmental sensor may include a protective coating over the first sensing element.

In combination with any of the above examples, the environmental sensor may include a second trench etched on the RDL. The environmental sensor may also include a second sensing element deposited in the second trench using inkjet material deposition. The first sensing element may be an inorganic sensing element and the second sensing element may be an organic sensing element.

In combination with any of the above examples, the material deposition process may be an inkjet deposition process.

In combination with any of the above examples, the material deposition process may be a three-dimensional printing process.

### BRIEF DESCRIPTION OF THE DRAWINGS

The figures illustrate examples of systems and methods for a highly integrated environmental sensor and process for manufacturing said sensor.

FIG. 1 is a side view of an integrated environmental sensor, according to examples of the present disclosure;

FIG. 2 illustrates a side view of an integrated sensor include multiple sensing elements and a sealed portion;

FIG. 3 illustrates a method of manufacturing an integrated sensor, according to examples of the present disclosure; and

FIG. 4 illustrates a more detailed method for manufacturing an integrated sensor, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a highly integrated environmental sensor and process for manufacturing said sensor is provided. The sensor may provide improved reliability and longevity. Additionally, the sensor may provide increased sensitivity to various gases and improved sensor signal to noise ratio (SNR). The sensor may be provided at a lower price point than prior sensors and the manufacturing process may allow for a large number of devices to be manufactured at a low price point. The sensor may be used in a variety of applications, such as smoke detectors, carbon monoxide detectors, building health sensors, agriculture sensors, and mining sensors.

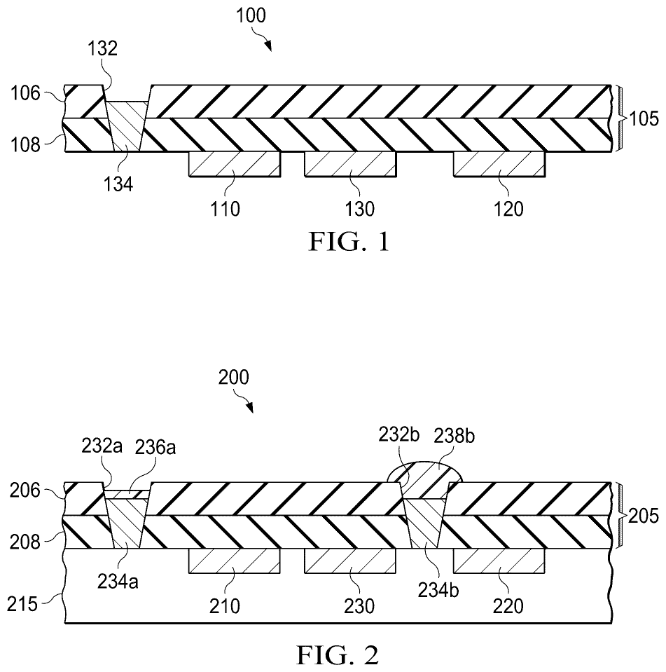

FIG. 1 is a side view of an integrated environmental sensor, according to examples of the present disclosure. Integrated sensor 100 may include redistribution layer (RDL) 105. Active semiconductor circuits, such as analog front-end circuit 110 and control circuit 120, and integrated passive device (IPD) circuit 130 may be provided on RDL 105.

RDL 105 may provide a mounting structure for the components of integrated sensor 100. RDL 105 may be one or more layers of metal on an integrated circuit to provide for arrangement of electrical connections. Active semiconductor circuits, such as analog front-end circuit 110, control circuit 120, and IPD circuit 130 are mounted to RDL 105, which create the integrated circuit for integrated sensor 100. RDL 105 may contain copper layer 106 and insulator layer 108. Copper layer 106 may contain traces to provide connections between the components of integrated sensor 100. Analog front-end circuit 110 and control circuit 120 may be mounted on RDL 105 and soldered to the copper traces. While one copper layer 106 and insulator layer 108 are shown in FIG. 1, RDL 105 may be formed of multiple copper layers 106 and insulator layers 108.

Analog front-end circuit 110 may receive analog signals (e.g., voltages) from sensing element 134 via IPD circuit 130 and convert the analog signal to a digital signal. Analog front-end circuit 110 may provide the digital signal to control circuit 120. Analog front-end circuit 110 may be coupled to IPD circuit 130 and control circuit 120 via any suitable method for connecting components to an RDL, such as soldering, wire bonding, flip-chip bonding, and tape automated bonding (TAB).

Control circuit 120 may be a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. Control circuit 120 may receive digital signals indicative of measurements from sensing element 134 from analog front-end circuit 110. Control circuit 120 may interpret the measurements. For example, control circuit 120 may perform calculations using the measurements, store the measurements, or trigger an action based on the measurement (e.g., activate an alarm, light, or transmit data to another device).

IPD circuit 130 may be an analog front-end circuit coupled to sensing element 134. IPD circuit 130 may provide an interface between sensing element 134 and the other components of integrated sensor 100 including analog front-end circuit 110 and control circuit 120. IPD circuit 130 may perform conditioning of the signal from sensing element 134 and may perform noise reduction to improve signal quality.

Sensing element 134 deposited in trench 132 may provide measurements of an environmental condition, such as, but not limited to, humidity, temperature, atmospheric pressure, or gases such as, but not limited to carbon monoxide, carbon dioxide, methane, propane, and others. Trench 132 may be etched on RDL 105 using any suitable etching technique including dry etching, wet etching, or any combination thereof. Sensing element 134 may be isolated to trench 132 on RDL 105. Sensing element 134 may be formed by depositing sensing element 134 into trench 132 using three-dimensional (3D) printing, an inkjet material deposition or silk-screening process. The inkjet process may involve a nozzle that deposits droplets of sensing element 134 into trench 132. The 3D printing process may use any suitable 3D printing technique including, but not limited to, fused deposition modeling (FDM), stereolithography (SLA), selective laser sintering (SLS), selective laser melting (SLM), binder jetting, and material jetting.

Sensing element 134 may be organic (e.g., doped Poly(3,4-ethylenedioxythiophene) polystyrene sulfonate (PEDOT:PSS), alcohol-dispersible formulation of PEDOT:PSS (PEDOT:F), and silicon dioxide (SiO₂)) or inorganic (e.g., doped metal-oxide, such as tin dioxide (SnO₂), zinc oxide (ZnO), and titanium dioxide (TiO₂)). In examples where sensing element 134 is organic, sensing element 134 may dry and form a film after the solvent evaporates. In some examples, integrated sensor 100 may be placed in an over to facilitate drying of sensing element 134. In examples where sensing element 134 is inorganic, sensing element 134 may then be annealed using a laser. The use of a laser annealing process may harden the inorganic sensing element 134 without affecting any organic sensing element 134 in another trench due to the precise aim and short duration of the laser.

Sensing element 134 may measure an environmental condition by changes in an environmental condition creating a change in an electrical property that generates a change in the resistance or capacitance of sensing element 134 that can be converted into a measurement of the environmental condition. For example, where sensing element 134 is a humidity sensor, sensing element 134 may be placed between two electrodes (e.g., an anode and cathode) that may be formed on RDL 105 and coupled to IPD circuit 130. As the humidity increases, sensing element 134 may absorb moisture, causing the resistance of sensing element 134 to increase. The change in the resistance may generate an electrical signal that may generate an electrical signal that may be measured and control circuit 120 may convert the change in capacitance to a humidity measurement.

While FIG. 1 illustrates two active semiconductor circuits (e.g., analog front-end circuit 110 and control circuit 120) and integrated passive device (IPD) circuit 130, integrated sensor 100 may include additional semiconductor elements such as, but not limited to, operational amplifiers, analog-to-digital converters, multiplexers (MUXs), field programmable gate arrays (FPGAs), application-specific integrated circuits (ASICs), digital signal processors (DSPs), and microcontrollers (MCUs).

FIG. 2 illustrates a side view of an integrated sensor include multiple sensing elements and a sealed portion, according to examples of the present disclosure.

Integrated sensor 200 includes some components in sealed portion 215. For example, active semiconductor circuits, such as analog front-end circuit 210, control circuit 220, and IPD circuit 230 may be contained within sealed portion 215. The components in sealed portion 215 are protected from the environment surrounding integrated sensor 200 to prevent damage to or contamination of the components in sealed portion 215. Sealed portion 215 may be created in any suitable manner, such as by applying an epoxy over the components in sealed portion 215 or using a ceramic or metal lid.

While FIG. 2 illustrates two active semiconductor circuits (e.g., analog front-end circuit 210 and control circuit 220) and integrated passive device (IPD) circuit 230, contained in sealed portion 215, integrated sensor 200 may include additional semiconductor elements such as, but not limited to, operational amplifiers, analog-to-digital converters, multiplexers (MUXs), field programmable gate arrays (FPGAs), application-specific integrated circuits (ASICs), digital signal processors (DSPs), and microcontrollers (MCUs).

Sensing elements 234a and 234b may not be included in sealed portion 215 such that sensing elements 234a and 234b are exposed to the environment surrounding integrated sensor 200. In some examples, sensing elements 234a and 234b may be covered by water or gas permeable membrane 238b, such as a specially tuned polymer. Water or gas permeable membrane 238b may protect sensing elements 234a and 234b while still allowing sensing elements 234a and 234b to respond to changes in environmental conditions (e.g., changes in temperature, humidity, or atmospheric pressure). In some examples, water or gas permeable membrane 238b may filter out unwanted particulates.

Integrated sensor 200 may include RDL 205. Analog front-end circuit 210, control circuit 220, IPD circuit 230, and sensing elements 234a and 234b may be provided on RDL 205. Analog front-end circuit 210, control circuit 220, and IPD circuit 230 may be similar to analog front-end circuit 110, control circuit 120, and IPD circuit 230 shown in FIG. 1.

Sensing elements 234a and 234b may be formed in trenches 232a and 232b, respectively. Trenches 232a and 232b may be etched on RDL 205 using any suitable etching technique including dry etching, wet etching, or any combination thereof. Trenches 232a and 232b may be etched adjacent to one another. Trench 232a may be spaced apart from trench 232b by any suitable amount. For example, trench 232a may be spaced between 0.5 millimeters to 3 millimeters apart from trench 232b. While trench 232a and trench 232b are shown in FIG. 2 as having similar sizes, trench 232a and trench 232b may be of difference sizes. Sensing element 234a may be isolated from sensing element 234b by containing sensing elements 234a and 234b in the respective trenches 232a and 232b.

Sensing elements 234a and 234b may be any combination of organic and inorganic sensing elements. For example, sensing element 234a and 234b may both be organic, both be inorganic, or sensing element 234b may be organic while the other of sensing element 234a may be inorganic. In the example where sensing element 234a is inorganic, sensing element 234a may be an inorganic material such as doped metal-oxide, such as tin dioxide (SnO₂), zinc oxide (ZnO), and titanium dioxide (TiO₂). Where sensing element 234b is organic, sensing element 234b may be an organic material such as doped Poly(3,4-ethylenedioxythiophene) polystyrene sulfonate (PEDOT:PSS), alcohol-dispersible formulation of PEDOT:PSS (PEDOT:F), and silicon dioxide (SiO₂).

Sensing element 234a may be formed by depositing sensing element 234a into trench 232a using a material deposition process, such as, but not limited to, 3D printing, an inkjet material deposition, or silk-screening process. The inkjet process may involve a nozzle that deposits droplets of sensing element 234a into trench 232b. Sensing element 234b may be formed in a similar manner, depositing sensing element 234b into trench 232b using a material deposition process, such as, but not limited to, 3D printing, an inkjet material deposition, or silk-screening process. Multiple nozzles may be used such that a first nozzle deposits sensing element 234a into trench 232a while a second nozzle deposits sensing element 234b into trench 232b.

After sensing elements 234a and 234b are deposited into trenches 232a and 232b, respectively, sensing elements 234a and 234b may be cured. The curing process may be different based on whether sensing elements 234a and 234b are organic or inorganic. In examples where sensing element 234a is inorganic and sensing element 234b is organic, sensing element 234a may be annealed using a laser. The use of a laser annealing process may harden inorganic sensing element 234a without affecting organic sensing element 234b in trench 232b due to the precise aim and short duration of the laser. Sensing element 234b may dry and form a film after the solvent mixed with sensing element 234b during deposition evaporates.

Sensing elements 234a and 234b may measure an environmental condition by changes in an environmental condition creating a change in an electrical property that generates a change in the resistance of sensing elements 234a and 234b that can be converted into a measurement of the environmental condition. For example, where sensing element 234a is a humidity sensor, sensing element 234a may be placed between two electrodes (e.g., an anode and cathode) that may be formed on RDL 205 and coupled to IPD circuit 230. As the humidity increases, sensing element 234a may absorb moisture, causing the capacitance of sensing element 234a to increase. The change in the capacitance may be measured and the control circuit may convert the change in capacitance to a humidity measurement. As another example, where sensing element 234b is a temperature sensor, as the temperature increases, sensing element 234a may expand or contract, causing the resistance of sensing element 234b to change. The change in the resistance may be measured and the control circuit may convert the change in resistance to a temperature measurement.

In some examples, protective coating 236a may be applied to sensing element 234a, sensing element 234b, or both. For example, protective coating 236a may be applied by nitriding. Protective coating 236a may protect sensing element 234a, sensing element 234b, or both against ionic contamination or other forms of contamination.

While integrated sensor 200 is shown in FIG. 2 as having two sensing elements 234a and 234b, integrated sensor 200 may include more or fewer sensing elements 234a or 234b. Additionally, integrated sensor 200 may contain more than one sensing element 234a including protective coating 236a. Further, integrated sensor 200 may contain more than one sensing element 234b including water or gas permeable membrane 238b. Sensing element 234a and 234b may be any suitable type of environmental sensor, such as resistive, capacitive, inductive, or any combination thereof. A given sensing element 234a or 234b may be used to detect a given environmental condition. For example, sensing element 234a may be used to detect humidity, sensing element 234b may be used to detect temperature, and a third environmental sensor (not shown) may be used to detect carbon monoxide. Sensing elements 234a and 234b may be coupled to an analog front-end circuit and isolated from one another.

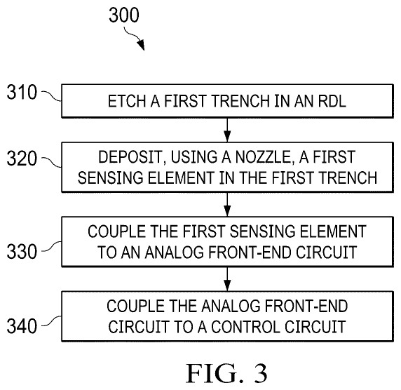

FIG. 3 illustrates a method of manufacturing an integrated sensor, such as integrated sensor 100 or 200 shown in FIGS. 1 and 3, respectively, according to examples of the present disclosure. Method 300 may be implemented using an inkjet manufacturing technique, in combination with any other system operable to implement method 300. Although examples have been described above, other variations and examples may be made from this disclosure without departing from the spirit and scope of these disclosed examples.

Method 300 may begin at block 310 where a first trench may be etched in an RDL. The first trench may be etched in the RDL using any suitable etching technique including dry etching, wet etching, or any combination thereof. The RDL may provide a mounting structure for the components of the integrated sensor. The RDL may be formed of one or more copper layers and insulator layers in which traces are etched to provide connections between the components of the integrated sensor. The trenches may be formed by any suitable method for creating trenches in an RDL including using etchants to remove portions of the RDL areas where a sensing element will be placed to create an environmental sensor.

At block 320, a first sensing element may be deposited in the first trench using a nozzle. The first trench is created at block 310. The first sensing element may be deposited into the first trench using a material deposition process, such as, but not limited to, 3D printing, an inkjet material deposition, or silk-screening process. The inkjet process may involve a nozzle (e.g., an inkjet head) that deposits droplets of the first sensing element into the first trench. The first sensing element may be organic (e.g., doped Poly(3,4-ethylenedioxythiophene) polystyrene sulfonate (PEDOT:PSS), alcohol-dispersible formulation of PEDOT:PSS (PEDOT:F), and silicon dioxide (SiO₂)) or inorganic (e.g., doped metal-oxide, such as tin dioxide (SnO₂), zinc oxide (ZnO), and titanium dioxide (TiO₂)).

At block 330, the first sensing element may be coupled to an analog front-end circuit. The analog front-end circuit may be coupled to the first sensing element via any suitable method for connecting components to an RDL, such as soldering, wire bonding, flip-chip bonding, and tape automated bonding (TAB). In some examples, the first sensing element may be coupled to electrodes and the electrodes may be coupled to the analog front-end circuit.

At block 340, the analog front-end circuit may be coupled to a control circuit. The analog front-end circuit may be coupled to the control circuit via any suitable method for connecting components to a RDL, such as soldering, wire bonding, flip-chip bonding, and TAB. The control circuit may receive measurements from the sensing elements via the analog front-end circuit and interpret the measurements. For example, the control circuit may perform calculations using the measurements, store the measurements, or trigger an action based on the measurement (e.g., activate an alarm, light, or transmit data to another device).

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

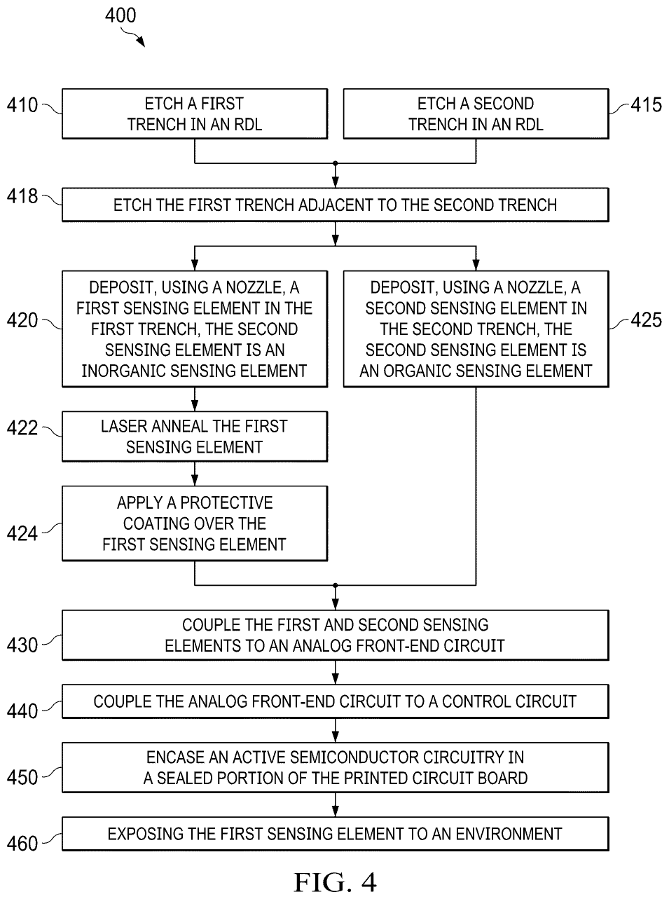

FIG. 4 illustrates a more detailed method for manufacturing an integrated sensor, such as integrated sensor 100 or 200 shown in FIGS. 1 and 2, respectively, according to examples of the present disclosure. Method 400 may be implemented using an inkjet manufacturing technique, in combination with any other system operable to implement method 400. Although examples have been described above, other variations and examples may be made from this disclosure without departing from the spirit and scope of these disclosed examples.

Method 400 may begin at block 410 where a first trench may be etched in an RDL. The first trench may be etched in the RDL using any suitable etching technique including dry etching, wet etching, or any combination thereof. The RDL may provide a mounting structure for the components of the integrated sensor. The RDL may be formed of one or more copper layers and insulator layers in which traces are etched to provide connections between the components of the integrated sensor. The trenches may be formed by any suitable method for creating trenches in an RDL including using etchants to remove portions of the RDL areas where a sensing element will be placed to create an environmental sensor.

At block 415, a second trench may be etched in the RDL. The second trench may be etched in the RDL using any suitable etching technique including dry etching, wet etching, or any combination thereof. The second trench may be etched using a similar process as the process used to etch the first trench at block 410. In some examples, the first trench and the second trench may be etched at the same time. In other examples, the first trench and the second trench may be etched at the different times.

At block 418, the first trench may be etched adjacent to the second trench.

At block 420, a first sensing element may be deposited in the first trench using a nozzle. The first trench is created at block 410. The first sensing element may be deposited into the first trench using a material deposition process, such as, but not limited to, an inkjet material deposition, or silk-screening process. The inkjet process may involve a nozzle (e.g., an inkjet head) that deposits droplets of the first sensing element into the first trench. The first sensing element may be inorganic (e.g., doped metal-oxide, such as tin dioxide (SnO₂), zinc oxide (ZnO), and titanium dioxide (TiO₂)).

At block 422, the first sensing element may be laser annealed. For example, the first sensing element may be doped and may then be sintered or annealed using a laser, such as an 808 nm diode laser.

At block 424, the protective coating may be applied over the first sensing element. For example, the protective coating may be applied by nitriding. The coating may provide additional robustness against ionic contamination or other forms of contamination when the integrated sensor is in use.

At block 425, a second sensing element may be deposited in the second trench using a nozzle. The second trench is created at block 415. The second sensing element may be deposited into the first trench using a material deposition process, such as, but not limited to, 3D printing, an inkjet material deposition, or silk-screening process. The inkjet process may involve a nozzle (e.g., an inkjet head) that deposits droplets of the second sensing element into the first trench. The second sensing element may be organic (e.g., doped Poly (3,4-ethylenedioxythiophene) polystyrene sulfonate (PEDOT:PSS), alcohol-dispersible formulation of PEDOT:PSS (PEDOT:F), and silicon dioxide (SiO₂). In some examples, the first sensing element and the second sensing element may be deposited at the same time. In other examples, the first sensing element and the second sensing element may be deposited at the different times.

At block 430, the first sensing element and the second sensing element may be coupled to an analog front-end circuit. The analog front-end circuit may be coupled to the first sensing element and the second sensing element via any suitable method for connecting components to an RDL, such as soldering, wire bonding, flip-chip bonding, and tape automated bonding (TAB). In some examples, the first sensing element and the second sensing element may be coupled to electrodes and the electrodes may be coupled to the analog front-end circuit.

At block 440, the analog front-end circuit may be coupled to a control circuit. The analog front-end circuit may be coupled to the control circuit via any suitable method for connecting components to an RDL, such as soldering, wire bonding, flip-chip bonding, and TAB. The control circuit may receive measurements from the sensing elements via the analog front-end circuit and interpret the measurements. For example, the control circuit may perform calculations using the measurements, store the measurements, or trigger an action based on the measurement (e.g., activate an alarm, light, or transmit data to another device).

At block 450, active semiconductor circuits, such as the control circuit and the analog front-end circuit, may be encased in a sealed portion of the RDL. The components in the sealed portion may be protected from the environment surrounding the RDL to prevent damage to or contamination of the control circuit and the analog front-end circuit. The sealed portion may be created in any suitable manner, such as by applying an epoxy over the components in the sealed portion or using a ceramic or metal lid.

At block 460, the first sensing element may be exposed to an environment. In some examples, the first sensing element may be covered by a water or gas permeable membrane, such as a specially tuned polymer.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

The manufacturing process disclosed for manufacturing the environmental sensors may allow for rapid, accurate, and low-cost dispensing of a sensing element without using sputtering, physical vapor deposition (PVD), or chemical vapor deposition (CVD).

Although examples have been described above, other variations and examples may be made from this disclosure without departing from the spirit and scope of these disclosed examples.

1. An integrated sensor, comprising:
a redistribution layer (RDL);
a control circuit coupled to the RDL;
an analog front-end circuit coupled to the RDL and the control circuit; and
an environmental sensor coupled to the analog front-end circuit, the environmental sensor including a first sensing element deposited in a first trench etched on the RDL using inkjet material deposition.

2. The integrated sensor of claim 1, wherein an active semiconductor circuit is contained in a sealed portion of the RDL.

3. The integrated sensor of claim 1, wherein the first sensing element is laser annealed.

4. The integrated sensor of claim 1, wherein the environmental sensor includes a protective coating over the first sensing element.

5. The integrated sensor of claim 1, comprising:
a second environmental sensor coupled to the analog front-end circuit, the second environmental sensor including a second sensing element deposited in a second trench etched on the RDL using inkjet material deposition;
wherein the first sensing element is an inorganic sensing element and the second sensing element is an organic sensing element.

6. The integrated sensor of claim 5, wherein the first trench is adjacent to the second trench.

7. The integrated sensor of claim 1, wherein the first sensing element is exposed to an environment.

8. A method, comprising:
etching a first trench in a redistribution layer (RDL);
depositing, using a nozzle, a first sensing element in the first trench;
coupling the first sensing element to an analog front-end circuit; and
coupling the analog front-end circuit to a control circuit.

9. The method of claim 8, comprising encasing an active semiconductor circuit in a sealed portion of the RDL.

10. The method of claim 8, comprising laser annealing the first sensing element.

11. The method of claim 8, comprising applying a protective coating over the first sensing element.

12. The method of claim 8, comprising:
etching a second trench in the RDL;
depositing, using a second nozzle, a second sensing element in the second trench; and
coupling the second sensing element to the analog front-end circuit;
wherein the first sensing element is an inorganic sensing element and the second sensing element is an organic sensing element.

13. The method of claim 12, wherein the first trench is adjacent to the second trench.

14. The method of claim 8, comprising exposing the first sensing element to an environment.

15. An environmental sensor, comprising:
a redistribution layer (RDL) containing a first trench etched on the RDL; and
a first sensing element deposited in the first trench using a material deposition process.

16. The environmental sensor of claim 15, wherein the first sensing element is laser annealed.

17. The environmental sensor of claim 15, comprising a protective coating over the first sensing element.

18. The environmental sensor of claim 15, comprising:
a second trench etched on the RDL; and
a second sensing element deposited in the second trench using inkjet material deposition;
wherein the first sensing element is an inorganic sensing element and the second sensing element is an organic sensing element.

19. The environmental sensor of claim 15, wherein the material deposition process is an inkjet deposition process.

20. The environmental sensor of claim 15, wherein the material deposition process is a three-dimensional printing process.
